(19) United States
(12) Patent Application Publication
(10) Pub. No.: US 2026/0231317 A1
(43) Pub. Date: Aug. 6, 2026

(54) HEAT DISSIPATION DEVICE AND ELECTRONIC DEVICE

(71) Applicant: AAC Microtech (Changzhou) Co., Ltd., Changzhou City (CN)

(72) Inventors: Xiang Pan, Changzhou (CN); Shasha Xu, Changzhou (CN); Bingyue Bai, Changzhou (CN)

(21) Appl. No.: 19/331,989

(22) Filed: Sep. 17, 2025

Related U.S. Application Data
(63) Continuation of application No. PCT/CN2025/074056, filed on Jan. 22, 2025.

(51) Int. Cl. H05K 1/02; H05K 7/20

(52) U.S. Cl. CPC H05K 1/0203; H05K 7/20327; H05K 7/20336; H05K 2201/066; H05K 2201/10409; H05K 2201/10598

(57) ABSTRACT

A heat dissipation device and an electronic device. The heat dissipation device includes a circuit board, a heat source device and a liquid cooling plate; the heat source device is fixedly mounted to the circuit board; the liquid cooling plate includes a first cover plate, a second cover plate and an intermediate plate sandwiched between the first cover plate and the second cover plate; a side of the intermediate plate close to the first cover plate is recessed to form a first accommodating space, and a side of the intermediate plate close to the second cover plate is recessed to form a second accommodating space; the liquid cooling plate further includes a heat dissipation member arranged in the first accommodating space, and the first accommodating space is filled with phase change liquid; The heat dissipation performance of the heat dissipation device according to the present disclosure is better.

### TECHNICAL FIELD

The present disclosure relates to the technical field of heat dissipation, and in particular, to a heat dissipation device and an electronic device.

### BACKGROUND

With the development of electronic and electrical technologies and the improvement of user demands, various electronic products in daily life and scientific research and education have more and more functions and higher and higher power, and heat generation of the electronic product is more and more serious. A vapor chamber (VC) is a light and thin heat dissipation element, and due to a divergent vapor path and a good 2D surface heat conduction capability, the vapor chamber can be applied to various electronic products, enhances the heat dissipation effect of the products, and thus is an ideal solution to the heat dissipation problem of various electronic products currently.

In a vapor chamber solution in the prior art, the vapor chamber is generally arranged between a heat source device and a metal shell of the product, and after being conducted to the vapor chamber, the heat generated by the heat source device is dissipated through heat conduction of the metal shell of the product. However, the vapor chamber solution in the prior art depends on passive heat dissipation of the metal shell of the product, and for a large chip module with high generated heat, such as a heat source device module of a notebook computer, the passive heat dissipation effect based on shell attachment is limited, and when the notebook computer is required to run at a high performance, performance problems are easily caused because heat is not dissipated in time, that is, the heat dissipation effect of the prior art is poor.

Therefore, it needs to provide a new heat dissipation solution to solve the above problems.

### SUMMARY

The present disclosure aims to provide a heat dissipation device with a better heat dissipation effect and an electronic device.

In order to solve the above technical problem, the present disclosure provides a heat dissipation device, including a circuit board, a heat source device and a liquid cooling plate. The heat source device is fixedly mounted to the circuit board. The liquid cooling plate includes a first cover plate, a second cover plate and an intermediate plate sandwiched between the first cover plate and the second cover plate; a side of the intermediate plate close to the first cover plate is recessed towards the second cover plate to form a first accommodating space, the liquid cooling plate further includes a heat dissipation member arranged in the first accommodating space, and the first accommodating space is filled with phase change liquid; a side of the intermediate plate close to the second cover plate is recessed towards the first cover plate to form a second accommodating space, and a liquid inlet hole and a liquid outlet hole which are communicated with the second accommodating space are formed in the intermediate plate; the liquid cooling plate further includes a liquid inlet tube communicated with the second accommodating space through the liquid inlet hole and a liquid outlet tube communicated with the second accommodating space through the liquid outlet hole; and the second accommodating space is filled with cooling liquid. The second cover plate is provided with an avoiding hole isolated from the second accommodating space, and the heat source device passes through the avoiding hole to be attached to the intermediate plate.

As an improvement, the intermediate plate includes a concave portion defining the second accommodating space together with the second cover plate, and an attachment portion attached to the heat source device; and a surface of the attachment portion facing the heat source device is recessed away from the second cover plate to form a groove, and the groove includes a groove bottom surface attached to the heat source device.

As an improvement, the heat source device includes a first device having a first thickness and a second device having a second thickness smaller than the first thickness, a surface of the first device fixedly mounted to the circuit board and a surface of the second device fixedly mounted to the circuit board are located in a same horizontal plane, the attachment portion includes a convex portion protruding towards the heat source device from the groove bottom surface, and the second device is attached to the convex portion.

As an improvement, the heat dissipation device further includes a plurality of support structures arranged at intervals in the second accommodating space, and the plurality of support structures arranged in the second accommodating space are supported between the second cover plate and the concave portion.

As an improvement, the second cover plate is provided with a first interface mounting position and a second interface mounting position which directly face the liquid inlet hole and the liquid outlet hole respectively, and the liquid inlet tube is clamped at the first interface mounting position and is communicated with the liquid inlet hole to form a liquid inlet channel for communicating the second accommodating space with an outside; and the liquid outlet tube is clamped at the second interface mounting position and is communicated with the liquid outlet hole to form a liquid outlet channel for communicating the second accommodating space with the outside.

As an improvement, the heat dissipation device further includes a fixing screw, a threaded hole and a fixing hole. The threaded hole is formed at a side of the second cover plate close to the circuit board, the fixing hole passes through the circuit board and directly faces the threaded hole, and the fixing screw passes through the fixing hole to be fixedly connected to the threaded hole in a threaded manner along a direction from the circuit board to the liquid cooling plate.

As an improvement, the liquid cooling plate includes a plurality of heat dissipation members arranged in an array, and the plurality of heat dissipation members are a vapor chamber with a capillary structure.

The present disclosure further provides an electronic device including the heat dissipation device described above.

### BRIEF DESCRIPTION OF DRAWINGS

To better describe the technical solutions in embodiments of the present disclosure, the following briefly describes the accompanying drawings required for the description of the embodiments. Apparently, the accompanying drawings in the following description show merely some embodiments of the present disclosure, and a person of ordinary skill in the art may still derive other drawings from these accompanying drawings without creative efforts.

FIG. 1 is a schematic perspective structural diagram of a heat dissipation device according to an embodiment of the present disclosure;

FIG. 2 is a sectional view taken along A-A of the schematic perspective structural diagram of the heat dissipation device shown in FIG. 1;

FIG. 3 is a schematic overall exploded structural diagram of a heat dissipation device according to an embodiment of the present disclosure; and

FIG. 4 is a schematic exploded structural diagram of a liquid cooling plate in a heat dissipation device according to an embodiment of the present disclosure.

### DESCRIPTION OF EMBODIMENTS

The technical solutions in the embodiments of the present disclosure are described with reference to the accompanying drawings in the embodiments of the present disclosure, and apparently, the described embodiments are not all of but only some of the embodiments of the present disclosure. All other embodiments obtained by a person of ordinary skill in the art based on the embodiments of the present disclosure without creative efforts shall fall within a scope of the present disclosure.

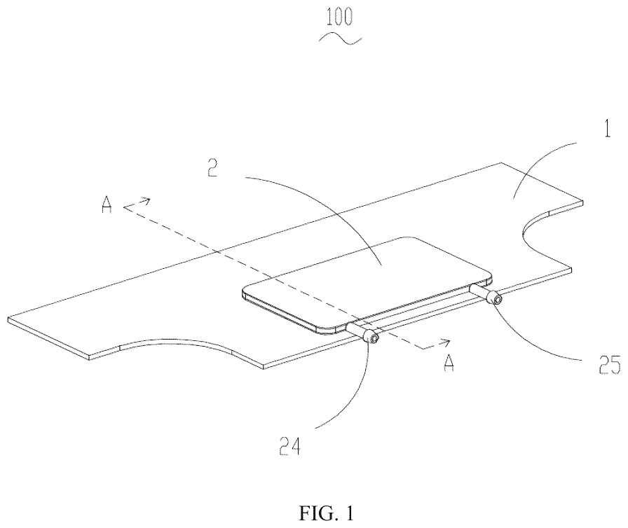

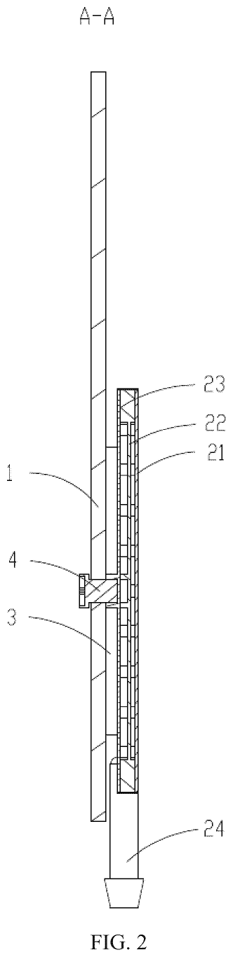

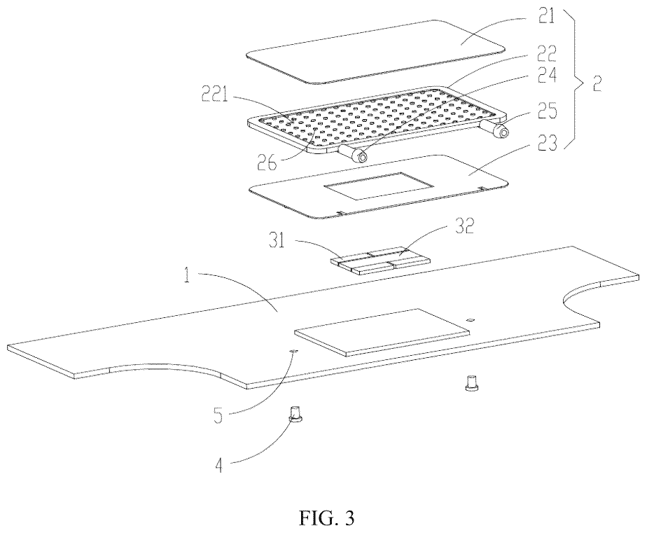

Referring to FIG. 1 to FIG. 4, an embodiment of the present disclosure provides a heat dissipation device 100, including a circuit board 1, a liquid cooling plate 2 and a heat source device 3.

The heat source device 3 is fixedly mounted to the circuit board 1.

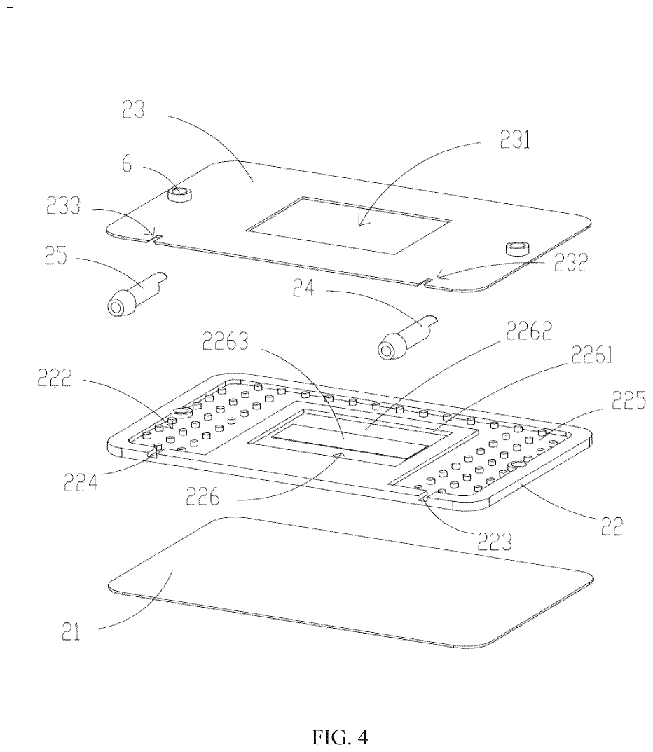

Referring to FIG. 4, the liquid cooling plate 2 includes a first cover plate 21, a second cover plate 23 and an intermediate plate 22 sandwiched between the first cover plate 21 and the second cover plate 23. A side of the intermediate plate 22 close to the first cover plate 21 is recessed towards the second cover plate 23 to form a first accommodating space 221, the liquid cooling plate 2 further includes a heat dissipation member 20 arranged in the first accommodating space 221, and the first accommodating space 221 is filled with phase change liquid. A side of the intermediate plate 22 close to the second cover plate 23 is recessed towards the first cover plate 21 to form a second accommodating space 222, and a liquid inlet hole 223 and a liquid outlet hole 224 which are communicated with the second accommodating space 222 are formed in the intermediate plate 22. The liquid cooling plate 2 further includes a liquid inlet tube 24 communicated with the second accommodating space 222 through the liquid inlet hole 223, and a liquid outlet tube 25 communicated with the second accommodating space 222 through the liquid outlet hole 224. The second accommodating space 222 is filled with cooling liquid. The second cover plate 23 is provided with an avoiding hole 231 isolated from the second accommodating space 222, and the heat source device 3 passes through the avoiding hole 231 to be attached to the intermediate plate 22.

The heat generated by the heat source device 3 is transferred into the first accommodating space 221, and is uniformly dispersed in the first accommodating space 221 under the action of the heat dissipation member 20 and the phase change liquid, and then is transferred to the second accommodating space 222; the cooling liquid in the second accommodating space 222 circulates through the liquid inlet tube 24 and the liquid outlet tube 25, so as to realize rapid heat dissipation.

In this embodiment, the heat dissipation member 20 is a vapor chamber with a capillary structure. For example, the liquid cooling plate 2 includes a plurality of heat dissipation members 20 arranged in an array, so as to further enhance the heat dissipation effect of the heat dissipation device 100.

Generally, the liquid inlet tube 24 and the liquid outlet tube 25 each are connected to an external condensation pump to form a liquid cooling channel for transporting the cooling liquid in the second accommodating space 222 back and forth, and the cooling liquid moves rapidly through the liquid cooling channel, dissipates heat in conjunction with external apparatuses, such as cooling fins and fans, and returns to the second accommodating space 222, so that the liquid cooling plate 2 maintains a low temperature.

In the embodiments of the present disclosure, the heat source device 3 is directly attached to and contacts the intermediate plate 22, and the heat generated thereof can be directly transferred into the first accommodating space 221 through the intermediate plate 22, thus achieving a better heat dissipation effect compared with a case of contact with the first cover plate 21 and the second cover plate 23.

In an example, the intermediate plate 22 includes a concave portion 225 defining the second accommodating space 222 together with the second cover plate 23, and an attachment portion 226 attached to the heat source device 3. A surface of the attachment portion 226 facing the heat source device 3 is recessed away from the second cover plate 23 to form a groove 2261, and the groove 2261 includes a groove bottom surface 2262 attached to the heat source device 3. When having a uniform thickness, the heat source device 3 is attached to the groove bottom surface 2262 to ensure that the heat is transferred into the first accommodating space 221 to the maximum extent.

Further, the heat source device 3 includes a first device 31 having a first thickness and a second device 32 having a second thickness smaller than the first thickness, a surface of the first device 31 fixedly mounted to the circuit board 1 and a surface of the second device 32 fixedly mounted to the circuit board 1 are located in a same horizontal plane, the attachment portion 224 includes a convex portion 2263 protruding towards the heat source device 3 from the groove bottom surface 2262, and the second device 32 is attached to the convex portion 2263. By providing the convex portion 2263, when the heat source device 3 includes devices having different thicknesses, the heat source device can be tightly attached to the intermediate plate 22, so as to achieve a good heat dissipation effect.

The second cover plate 23 is provided with a first interface mounting position 232 and a second interface mounting position 233 which directly face the liquid inlet hole 223 and the liquid outlet hole 224, respectively, and the liquid inlet tube 24 is clamped at the first interface mounting position 232 and is communicated with the liquid inlet hole 223 to form a liquid inlet channel for communicating the second accommodating space 222 with the outside; the liquid outlet tube 25 is clamped at the second interface mounting position 233 and is communicated with the liquid outlet hole 224 to form a liquid outlet channel for communicating the second accommodating space 222 with the outside. The arrangement of the first interface mounting position 232 and the second interface mounting position 233 facilitates mounting of the liquid inlet tube 24 and the liquid outlet tube 25.

The heat dissipation device 100 further includes a fixing screw 4, a threaded hole 5 and a fixing hole 6. The threaded hole 5 is formed at a side of the second cover plate 23 close to the circuit board 1, the fixing hole 6 passes through the circuit board 1 and directly faces the threaded hole 5. The fixing screw 4 passes through the fixing hole 5 to be fixedly connected to the threaded hole 6 in a threaded manner along a direction from the circuit board 1 to the liquid cooling plate 2. In an example, for a plate-type liquid cooling plate 2, a combination structure of a plurality of fixing screws 4, threaded holes 5 and the fixing holes 6 may be designed to stably fix the whole plate, so that the liquid cooling plate 2 and a surface of the heat source device 3 have a certain contact surface pressure, and the attachment thereof is tight.

In the embodiments of the present disclosure, in an example, the liquid cooling plate 2 is manufactured based on an electrochemical plating (ECP) process, which is a process for depositing metal copper on a semiconductor substrate by an electrochemical method. The liquid cooling plate 2 in the embodiments of the present disclosure may be made by the ECP process with a high heat conduction material as a substrate, and the substrate material may be copper, aluminum, stainless steel, titanium alloy, or the like, which have a good heat conduction performance.

The heat dissipation device 100 further includes a plurality of support structures 26 arranged at intervals in the second accommodating space 222. The support structure 26 arranged in the second accommodating space 222 is supported between the second cover plate 22 and the concave portion 225. The design of the support structure 26 inside the second accommodating space 222 is beneficial to increasing the heat exchange area of the intermediate plate 22, so as to improve the overall heat conduction and heat dissipation effects of the heat dissipation device 100.

An embodiment of the present disclosure further provides an electronic device, including the heat dissipation device 100 according to the above embodiments. It can be understood that the electronic device designed based on the heat dissipation device 100 according to the embodiments of the present disclosure can achieve a good heat dissipation performance based on the vapor chamber embedding heat conduction design of the heat dissipation device 100 and the efficient heat dissipation structure of the liquid cooling plate, reference can be made to the description of the above embodiments, and details are not repeated herein.

Compared with the related art, the heat dissipation device according to the present disclosure includes the circuit board, the heat source device and the liquid cooling plate, and the heat source device is fixedly mounted to the circuit board; the liquid cooling plate includes the first cover plate, the second cover plate and the intermediate plate sandwiched between the first cover plate and the second cover plate, a side of the intermediate plate close to the first cover plate is recessed towards the second cover plate to form the first accommodating space, the liquid cooling plate further includes the heat dissipation member arranged in the first accommodating space, and the first accommodating space is filled with the phase change liquid; a side of the intermediate plate close to the second cover plate is recessed towards the first cover plate to form the second accommodating space, and the liquid inlet hole and the liquid outlet hole which are communicated with the second accommodating space are formed in the intermediate plate; the liquid cooling plate further includes the liquid inlet tube communicated with the second accommodating space through the liquid inlet hole and the liquid outlet tube communicated with the second accommodating space through the liquid outlet hole; the second accommodating space is filled with the cooling liquid; the second cover plate is provided with the avoiding hole isolated from the second accommodating space, and the heat source device passes through the avoiding hole to be attached to the intermediate plate. In the above-mentioned structure, based on the structure of the intermediate plate, the temperature equalization structure is embedded in the liquid cooling plate, and in conjunction with the efficient heat conduction capability of the temperature equalization structure and the quick heat dissipation capability of the liquid cooling plate, the overall heat conduction capability of the circuit board is improved, which is more beneficial to directly controlling heat generation of the heat source device on the circuit board, and compared with the related art, the heat dissipation device according to the present disclosure has a better heat dissipation performance.

The above description merely illustrates some embodiments of the present disclosure, and it should be noted that improvements can be made by those of ordinary skill in the art without departing from the concept of the present disclosure, and all of them shall fall within a scope of the present disclosure.

What is claimed is:

1. A heat dissipation device, comprising a circuit board, a heat source device and a liquid cooling plate,
wherein the heat source device is fixedly mounted to the circuit board;
the liquid cooling plate comprises a first cover plate, a second cover plate and an intermediate plate sandwiched between the first cover plate and the second cover plate; a side of the intermediate plate close to the first cover plate is recessed towards the second cover plate to form a first accommodating space, the liquid cooling plate further comprises a heat dissipation member arranged in the first accommodating space, and the first accommodating space is filled with phase change liquid; a side of the intermediate plate close to the second cover plate is recessed towards the first cover plate to form a second accommodating space, and a liquid inlet hole and a liquid outlet hole which are communicated with the second accommodating space are formed in the intermediate plate; the liquid cooling plate further comprises a liquid inlet tube communicated with the second accommodating space through the liquid inlet hole and a liquid outlet tube communicated with the second accommodating space through the liquid outlet hole; and the second accommodating space is filled with cooling liquid; and
the second cover plate is provided with an avoiding hole isolated from the second accommodating space, and the heat source device passes through the avoiding hole to be attached to the intermediate plate.

2. The heat dissipation device as described in claim 1, wherein the intermediate plate comprises a concave portion defining the second accommodating space together with the second cover plate, and an attachment portion attached to the heat source device; and a surface of the attachment portion facing the heat source device is recessed away from the second cover plate to form a groove, and the groove comprises a groove bottom surface attached to the heat source device.

3. The heat dissipation device as described in claim 2, wherein the heat source device comprises a first device having a first thickness and a second device having a second thickness smaller than the first thickness, a surface of the first device fixedly mounted to the circuit board and a surface of the second device fixedly mounted to the circuit board are located in a same horizontal plane, the attachment portion comprises a convex portion protruding towards the heat source device from the groove bottom surface, and the second device is attached to the convex portion.

4. The heat dissipation device as described in claim 2, further comprising a plurality of support structures arranged at intervals in the second accommodating space, wherein the plurality of support structures arranged in the second accommodating space are supported between the second cover plate and the concave portion.

5. The heat dissipation device as described in claim 1, wherein the second cover plate is provided with a first interface mounting position and a second interface mounting position which directly face the liquid inlet hole and the liquid outlet hole respectively, and the liquid inlet tube is clamped at the first interface mounting position and is communicated with the liquid inlet hole to form a liquid inlet channel for communicating the second accommodating space with an outside; and the liquid outlet tube is clamped at the second interface mounting position and is communicated with the liquid outlet hole to form a liquid outlet channel for communicating the second accommodating space with the outside.

6. The heat dissipation device as described in claim 1, further comprising a fixing screw, a threaded hole and a fixing hole, wherein the threaded hole is formed at a side of the second cover plate close to the circuit board, the fixing hole passes through the circuit board and directly faces the threaded hole, and the fixing screw passes through the fixing hole to be fixedly connected to the threaded hole in a threaded manner along a direction from the circuit board to the liquid cooling plate.

7. The heat dissipation device as described in claim 1, wherein the liquid cooling plate comprises a plurality of heat dissipation members arranged in an array, and the plurality of heat dissipation members are a vapor chamber with a capillary structure.

8. An electronic device, comprising a heat dissipation device comprising a circuit board, a heat source device and a liquid cooling plate,
wherein the heat source device is fixedly mounted to the circuit board;
the liquid cooling plate comprises a first cover plate, a second cover plate and an intermediate plate sandwiched between the first cover plate and the second cover plate; a side of the intermediate plate close to the first cover plate is recessed towards the second cover plate to form a first accommodating space, the liquid cooling plate further comprises a heat dissipation member arranged in the first accommodating space, and the first accommodating space is filled with phase change liquid; a side of the intermediate plate close to the second cover plate is recessed towards the first cover plate to form a second accommodating space, and a liquid inlet hole and a liquid outlet hole which are communicated with the second accommodating space are formed in the intermediate plate; the liquid cooling plate further comprises a liquid inlet tube communicated with the second accommodating space through the liquid inlet hole and a liquid outlet tube communicated with the second accommodating space through the liquid outlet hole; and the second accommodating space is filled with cooling liquid; and
the second cover plate is provided with an avoiding hole isolated from the second accommodating space, and the heat source device passes through the avoiding hole to be attached to the intermediate plate.
